(19) United States
(12) Patent Application Publication
(10) Pub. No.: US 2015/0341040 A1
(43) Pub. Date: Nov. 26, 2015

(54) Clock Generator and Switch-capacitor Circuit Comprising the Same

(71) Applicant: XINFENG QUANTEL TECHNOLOGIES (BEIJING) CO., LTD, Beijing (CN)

(72) Inventors: Song LIU, Beijing (CN); Feiqin YANG, Beijing (CN); Ke WU, Beijing (CN)

(21) Appl. No.: 14/758,345

(22) PCT Filed: Dec. 28, 2012
(86) PCT No.: PCT/CN2012/087834

§ 371 Date: Jun. 29, 2015

(51) Int. Cl. H03L 7/085; H03B 5/32; H03K 3/03

(52) U.S. Cl. CPC H03L 7/085; H03K 3/0322; H03B 5/32

(57) ABSTRACT

The invention provides a clock generator and a switch-capacitor circuit comprising the same, and pertains to the technical field of integrated circuit (IC) design. The clock generator comprises a non-overlapping clock signal generating module and a ring oscillator, a frequency detecting module, a comparator module and a programmable biasing signal generating module for forming a feedback circuit, wherein a biasing signal generated by the programmable biasing signal generating module is fed back and input to the ring oscillator so as to adjust the frequency of the third clock signal output by the ring oscillator, until the frequency of the third clock signal is compared as being substantially equal to the frequency of a standard clock signal in the comparator module. Moreover, the biasing signal can be fed back and input to the non-overlapping clock signal generating module so as to reduce the offset of the two phase clock time interval τ. The time interval τ between two phase clocks of the multiple phase non-overlapping clock signal output by the clock generator is stable and has a high accuracy, and the switch-capacitor circuit using the clock generator exhibits an excellent performance.

### FIELD OF THE INVENTION

The invention pertains to the technical field of integrated circuit (IC) design, relates to a clock generator, and in particular to a clock generator which is less susceptible to PVT factor and can generate a multiple phase non-overlapping clock signal as well as a switch-capacitor circuit applied with the clock generator.

### BACKGROUND

In IC design, some circuit modules in the chip needs to use a multiple phase clock signal, especially a multiple phase non-overlapping clock signal simultaneously, wherein a time interval is set between any two clock signals so that for the clock signals in each phase, any two clock signals will not be in an “on” status simultaneously at any timing. Therefore, a time sequence relationship between the clock signals in individual phases has to be well controlled so as to ensure non-overlapping.

FIG. 1 is a schematic view of a two-phase none-overlapping clock signal, wherein “clock 1” indicates of one clock signal and “clock 2” indicates of another clock signal. In the embodiment shown in FIG. 1, a phase difference between clock 1 and clock 2 is 180°, and the clock signals of the two phases must not be in an “on” status simultaneously at any timing. In order to ensure non-overlapping between clocks, a corresponding clock generator must ensure that a gap is kept between a trailing edge of any one of the clock signals and a rising edge of the other clock signal, which gap is referred to as a time interval between two phase clocks (i.e., the “τ” shown in FIG. 1).

The multiple-phase none-overlapping clock signal such as that shown in FIG. 1 has been widely used in integrated circuits. Moreover, the higher the time sequence accuracy is, the better performance the integrated circuit exhibits. Taking the two-phase none-overlapping clock signal as an example, it has been widely used in a switch-capacitor circuit. For example, in a sample and hold circuit of a AD converter, in order to achieve a sampling and amplifying function of the switch-capacitor circuit, a clock signal control is required to be provided therefore; in order to avoid a so-called “charge sharing” phenomenon in the switch-capacitor circuit and to reduce the destruct to the accuracy of information caused by charge-sharing, the switch circuit thereof generally adopts the two-phase none-overlapping clock signal shown in FIG. 1.

FIG. 2 is a schematic view of the circuit of a conventional clock generator for generating a two-phase none-overlapping clock signal shown in FIG. 1, wherein a phase inverter I0 is used for inverting clocks; an input end of the NOT-AND gate N1 is connected to a reference clock signal, the other input end is input with clock 2 signal, and the output end of the NOT-AND gate N1 is output to a first set of phase inverters (I11/I12/I13) connected in series sequentially; an input end of the NOT-AND gate N2 is connected to an inverted clock signal (I0 output), the other end of input with clock1 signal, and the output end of the NOT-AND gate N2 is output to a second set of phase inverters (I21/I22/I23) connected in series sequentially. The closed-loop circuit composed of the NOT-AND gates (N1, N2) and two sets of phase inverters (I11/I12/I13 and I21/I22/I23) can ensure a time interval τ between clock 1 and clock 2; the specific size of the time interval τ can be also determined by a delay (t) of the first set of phase inverters (I11/I12/I13) or the second set of phase inverters (I21/I22/I23).

However, in an actual integrated circuit, the clock generator generating a multiple-phase none-overlapping clock signal are easily affected by many factors such as process, voltage and/or temperature (abbreviated as PVT in the industry), and the time interval τ between the clocks of two phases will also be prone to offset with the variation of PVT. For example, when the batches of water are different, the time intervals τ may be different; when the environment temperatures are different, the time intervals τ may be different; and when the voltages of power source are different, the time intervals τ may be different. Therefore, in an existing clock generator, the time interval τ between any two phase clock signals generated thereby is not stable, and a large offset may easily occur. The larger the offset of the time interval τ is, the more easily the performance of the circuit system using the clock signal is affected. For example, in a switch-capacitor circuit, when the value of τ is shortened to a certain degree (due to a larger offset of τ), a “charge sharing” phenomenon might occur in the switch-capacitor circuit because of a delay mismatch of a buffer behind the clock generator, thus greatly reducing the performance of the switch-capacitor circuit.

### SUMMARY OF THE INVENTION

The object of the invention is to reduce the offset of the time interval τ between two phase clocks of a multiple phase non-overlapping clock signal and to improve the stability of the time interval τ between two phase clocks.

In order to achieve the above object or other objects, the invention provides the following technical solutions.

According to an aspect of the invention, a clock generator is provided, comprising a non-overlapping clock signal generating module (31) for generating a multiple phase non-overlapping clock signal, and further comprising:

a ring oscillator (32) for generating a third clock signal (clock3) which reflects the offset of the time interval (τ) between two phase clocks of the multiple phase non-overlapping clock signal;

a frequency detecting module (33) for detecting the frequency of a standard clock signal (clock4) input by the frequency detecting module (33) and the frequency of the third clock signal (clock3);

a comparator module (34) for comparing the frequency of the standard clock signal (clock4) and the frequency of the third clock signal (clock3);

a programmable biasing signal generating module (35) for adjustably outputting a biasing signal according to the comparison result output by the comparator module (34);

wherein the biasing signal is fed back and input to the ring oscillator (32) so as to adjust the frequency of the third clock signal (clock3) until the frequency of the third clock signal (clock3) is compared as be substantially equal to the frequency of the standard clock signal (clock4) in the comparator module (34); and

wherein, the biasing signal is fed back and input to the non-overlapping clock signal generating module (31) so as to reduce the offset of the time interval (τ) between two phase clocks.

In the clock generator according to an embodiment of the invention, the non-overlapping clock signal generating module (31) is disposed adjacent to the ring oscillator (32) in the chip and is manufactured in synchronization with the ring oscillator (32) in the same process.

Further, optionally, the phase inverter for generating delay used in the non-overlapping clock signal generating module (31) is the same as the phase inverter for generating delay used in the ring oscillator (32), and the layouts and structures of them are also the same.

In the clock generator according to any of the above embodiments, the delay (τ1) generated by the phase inverter used in the ring oscillator (32) is n times larger than the time interval (τ) between two phase clocks generated by the phase inverter used in non-overlapping clock signal generating module (31), wherein n is an integer larger than or equal to 1.

In the clock generator according to any of the above embodiments, a plurality of phase inverters used in the non-overlapping clock signal generating module (31) can be the same, or be different.

In the clock generator according to another embodiment of the invention, the offset of the time interval (τ) between two phase clocks is caused by the fact that the multiple phase non-overlapping clock signal is influenced by the factors of process, voltage and/or temperature.

In the clock generator according to any of the above embodiments, the influence on the third clock signal (clock3) by the factors of process, voltage and/or temperature is substantially equal to the influence on the multiple phase non-overlapping clock signal by the factors of process, voltage and/or temperature.

In the clock generator according to any of the above embodiments, the non-overlapping clock signal generating module (31) is a current controllable non-overlapping clock signal generating module (31), the ring oscillator (32) is a current controllable ring oscillator (32), and the biasing signal is a biasing current signal.

In the clock generator according to any of the above embodiments, the biasing current signal adjusts the magnitude of current according to the comparison result of the comparator module (34) so as to correct the frequency of the third clock signal (clock3) and the time interval (τ) between two phase clocks.

In the clock generator according to any of the above embodiments, the biasing signal is biased onto all the gate circuits of the ring oscillator (32), and the biasing signal is also biased onto all the gate circuits of the non-overlapping clock signal generating module (31).

In the clock generator according to any of the above embodiments, the multiple phase non-overlapping clock signal can be a multiple phase non-overlapping clock signal of two or more than two phases.

In the clock generator according to any of the above embodiments, a reference clock signal generated by crystal oscillator is input to the non-overlapping clock signal generating module (31).

In the clock generator according to any of the above embodiments, the standard clock signal (clock4) is not influenced by the factors of process, voltage and/or temperature.

In the clock generator according to any of the above embodiments, the time interval between two phase clocks of the multiple phase non-overlapping clock signal is controlled by the standard clock signal (clock4).

According to another aspect of the invention, a switch-capacitor circuit is provided, comprising any of the above described clock generators, wherein the multiple phase non-overlapping clock signal output by the clock generator is applied in the switch-capacitor circuit.

In the clock generator and switch-capacitor circuit provided by the invention, a feedback circuit (i.e., a compensation circuit or compensation system) is formed by the ring oscillator, the frequency detecting module, the comparator module and the programmable biasing signal generating module; the biasing signal is fed back and the frequency of the clock signal output by the ring oscillator is adjusted to be equal to the frequency of the standard clock signal, and meanwhile, the time interval between two phase clocks of the multiple phase non-overlapping clock signal can be also corrected in real time or in a one-time manner. Therefore, the offset of the time interval τ between two phase clocks is reduced so that it is substantially immune to the influence by the factors of PVT, etc. The time interval τ between two phase clocks of the multiple phase non-overlapping clock signal output by the clock generator is stable and has a high accuracy, and the switch-capacitor circuit using the clock generator exhibits an excellent performance.

### BRIEF DESCRIPTION OF THE DRAWINGS

The above and other objects and advantages of the invention will become completely apparent from the following detailed description with reference to the accompanying drawings, wherein identical or similar elements are denoted by identical reference signs.

FIG. 1 is a schematic view of a two-phase none-overlapping clock signal.

FIG. 2 is a schematic view of the circuit of a conventional clock generator for generating the two-phase none-overlapping clock signal shown in FIG. 1.

FIG. 3 is a schematic structure view of the clock generator according to an embodiment of the invention.

### DETAILED DESCRIPTION OF THE INVENTION

Some of the many possible embodiments of the invention will be described below in order to provide a basic understanding of the invention, and it is not intended to identify the crucial or decisive elements of the invention or limit the scope of protection. It is easily understood that according to the technical solutions of the invention, those skilled in the art can propose other alternative implementations without departing from the true spirit of the invention. Therefore, the following specific embodiments and drawings are merely exemplary description of the technical solutions of the invention, and should not be taken as the whole invention or as defining or limiting the technical solutions of the invention.

In the following description, in order to the make the description clear and concise, not all the many component shown in the drawings are described. Many components that enable those skilled in the art to completely carry out the invention are shown in the Drawings. For those skilled in the art, the operation of many components is familiar and obvious.

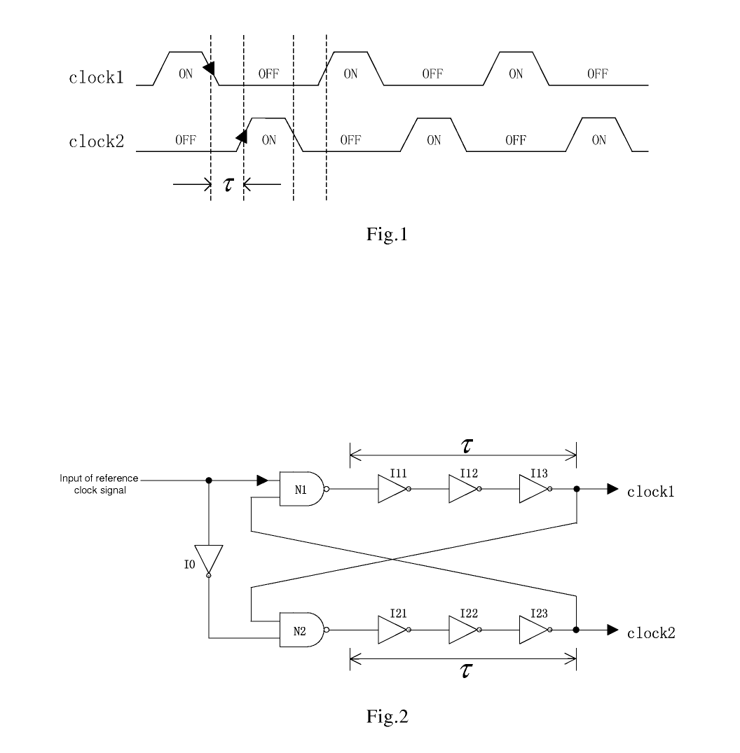

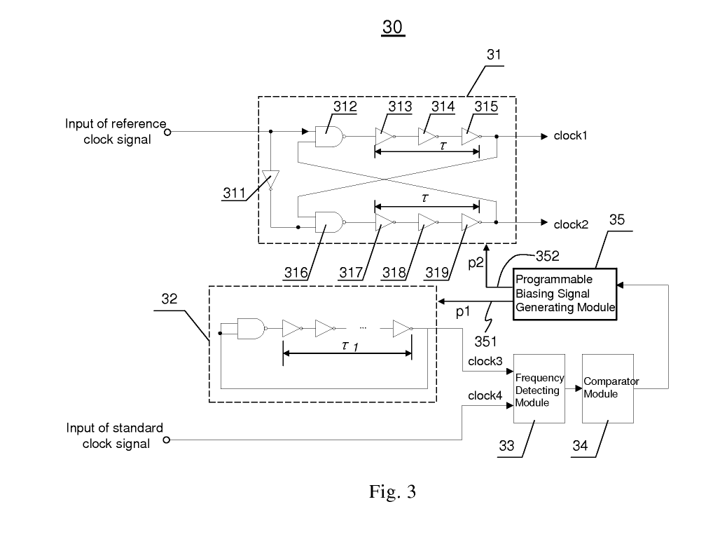

FIG. 3 is a schematic structure view of the clock generator according to an embodiment of the invention. In this embodiment, the clock generator 30 is used for generating a two-phase none-overlapping clock signal, i.e., clock signals clock1 and clock2. Therefore, the clock generator 30 necessarily comprises a non-overlapping clock signal generating module 31 which can output an input reference clock signal to generate two none-overlapping clock signals, i.e., clock signals clock1 and clock2. The reference clock signal can be generated by crystal oscillator, but not limited thereto. Specifically, as shown in FIG. 1, the non-overlapping clock signal generating module 31 uses several phase inverters and NOT-AND gates, wherein the phase inverter 311 is used for inverting the reference clock signal and further inputting the inverted reference clock signal to an end of the NOT-AND gate 316; an input end of the NOT-AND gate 312 is connected with the reference clock signal, and the other input end is feedback input by the clock signal clock2. The reference clock signal and the clock signal clock2 are processed in a NOT-AND logic by the NOT-AND gate 312 and then output to the phase inverter 311. Further, the phase inverters 313, 314 and 315 that are connected in series sequentially are used for generating delay, which is substantially equal to the time interval τ. Further, the phase inverter 315 outputs the clock signal clock1; the clock signal clock1 is input to another input end of the NOT-AND gate 316 in feedback, and the inverted reference clock signal and clock signal clock1 are processed in a NOT-AND logic by the NOT-AND gate 316 and then output to the phase invert 317. Further, the phase inverters 317, 318 and 319 that are connected in series sequentially are used for generating delay, which is substantially equal to the time interval τ. Further, the phase inverter 319 outputs the clock signal clock2; the clock signal clock1 is feedback input to the NOT-AND gate 312, and the clock signal clock2 is feedback input to the NOT-AND gate 316, thus ensuring a two phase clock time interval τ (referred to as “time interval τ” for short hereinafter) exists between clock1 and clock2. Not considering the influences of such factors as PVT, the offset of the time interval τ is substantially zero, i.e., the time interval τ is a certain predetermined constant value. However, under the influence of such factors as PVT, the variation of the frequencies of clock1 and clock2 enables the time interval τ to change and offset relative to the predetermined constant value, i.e., an offset of the two phase clock time interval τ is generated.

In order to reduce the offset generated by the time interval τ due to an influence by the PVT, preferably, the phase inverters 313, 314, 315, 317, 318 and 319 are the same phase inverters. Not only the structures and parameters of them are identical, but also the layout and arrangement are identical, and they are disposed adjacent to each other; therefore, the delay generated by the phase inverters 313, 314 and 315 are the same as the delay generated by the phase inverters 317, 318 and 319 to the greatest extent possible.

With continued reference to FIG. 3 the clock generator 30 further comprises a ring oscillator 32. Specifically, the ring oscillator 32 can be also mainly composed of NOT-AND gates and a plurality of phase inverters. The delay τ1 generated by the plurality of phase inverters determines the frequency of the clock signal clock3 output by the ring oscillator 32. In this embodiment, the ring oscillator 32 is disposed adjacent to the non-overlapping clock signal generating module 31 in the chip and is manufactured in synchronization with the non-overlapping clock signal generating module 31 in the same process. The NOT-AND gates used in the ring oscillator 32 are the same as the NOT-AND gates used in the non-overlapping clock signal generating module 31, the phase inverters used in the ring oscillator 32 are the same as the phase inverters used in the non-overlapping clock signal generating module 31, and the structure and layout of the phase inverters in the ring oscillator 32 are also the same as those of the phase inverters in the non-overlapping clock signal generating module 31. Therefore, the ring oscillator 32 and the non-overlapping clock signal generating module 31 can be easily made to have the same process (i.e., the same manufacture process), the same voltage (i.e., the same power source voltage) and the same temperature (i.e., the same environment temperature). The influence on the output clock signal clock3 of the ring oscillator 32 by the PVT is substantially equal to the influence on the output clock signals clock1 and clock2 of the non-overlapping clock signal generating module 31 by the PVT. Therefore, the variation in the frequency caused by the influence on the clock signal clock3 by PVT can reflect the offset of the two phase clock time interval τ between clock1 and clock2. In this embodiment, the frequency of clock3 is determined by the delay τ1 of the plurality of phase inverters connected in series used by clock3. When τ1 is equal to τ, the frequency of the clock signal clock3 is equal to the frequencies of the clock signal clock1 and clock2. Moreover, the ratio of ON/OFF of the clock signal clock3 is also the same as the ratio of ON/OFF of the clock signal clock1 or clock2. The larger the difference between the frequency of the clock signal clock3 and the frequency of the standard signal clock4 is, the larger the offset of the two phase clock time interval τ in the non-overlapping clock signal generating module 31 is (the t becomes larger or smaller), and vice-versa.

In other embodiments, when the clock generator 30 is applied to a high speed situation, in order to avoid a too short period of clock3 (or to avoid a too high frequency), a multiple relationship can be formed between τ1 and τ. That is, the number of the phase inverters used in the ring oscillator 32 is n times of the number of the phase inverters for generating the time interval τ used in the non-overlapping clock signal generating module 31 (n is an integer larger than or equal to 2, e.g., n=10). In this way, the frequency f3 of the clock signal clock3 is one n^{th} of the frequency of the clock signal clock1 or clock2. At this time, the influence on the ring oscillator 32 by the PVT is also consistent with the influence on the non-overlapping clock signal generating module 31 by the PVT.

With continued reference to FIG. 3, the clock generator 30 further comprises a frequency detecting module 33, to which the clock signal clock3 output from the ring oscillator 32 and the standard clock signal clock4 provided externally are input simultaneously. The frequency detecting module 33 can detect the frequency f3 of the clock signal clock3, and can also detect the frequency f4 of the standard clock signal clock4. The standard clock signal clock4 has a very high accuracy, and is substantially immune to the influence from PVT. The standard clock signal clock4 has the same frequency as the clock signal clock1 or clock2 generated by the non-overlapping clock signal generating module 31 when the offset of the two phase clock time interval τ is zero. Therefore, the two phase clock time interval between the two phase non-overlapping clock signals (clock1 and clock2) can be controlled by the standard clock signal clock4.

With continued reference to FIG. 3, the clock generator 30 further comprises a comparator module 34 and a programmable biasing signal generating module 35. The comparator module 34 can compare the frequency f3 of the clock signal clock3 with the frequency f4 of the clock signal clock4. If the frequencies f3 and f4 are not the same, it means that the ring oscillator 32 is influenced by the PVT, and an offset of the two phase clock time interval τ between the two phase non-overlapping clock signals has occurred. The comparator module 34 can output a control signal to the programmable biasing signal generating module 35 so that the programmable biasing signal generating module 35 can adjust the height of an output biasing signal. If the frequencies f3 and f4 are the same, it means that the ring oscillator 32 is substantially not influenced by the PVT, and an offset of the two phase clock time interval τ between the two phase non-overlapping clock signals has not occurred. The comparator module 34 outputs another control signal to the programmable biasing signal generating module 35 so that the programmable biasing signal generating module 35 still outputs a biasing signal of the same height.

In this embodiment, the output end 351 of the programmable biasing signal generating module 35 outputs a biasing signal p1 to the ring oscillator 32, and the output end 352 outputs a biasing signal p2 to the non-overlapping clock signal generating module 31, wherein the biasing signals p1 and p2 are the same. In case where the non-overlapping clock signal generating module 31 is a current controllable non-overlapping clock signal generating module and the ring oscillator 32 is a current controllable ring oscillator, the biasing signals p1 and p2 are the same biasing current signals, and the magnitude of the current of the biasing signals p1 and p2 can be adjustably output according to a comparison result of the frequencies f3 and f4 in the comparator module 34. Therefore, the variation in the magnitude of the output biasing current signals can further cause a change of the frequency of the ring oscillator 32, until the frequencies f3 and f4 are substantially the same. Meanwhile, the biasing current signal (p2) is also adjusted synchronously, and the frequencies of clock1 and clock2 can thus be adjusted, thus further reducing an offset of the two phase clock time interval τ. When the frequencies f3 and f4 are substantially the same, which means that an offset of the two phase clock time interval τ has been substantially eliminated, the accuracy of the output two phase non-overlapping clock signals (clock1 and clock2) is high, making it easier to ensure no overlapping will occur between the two clock signals (clock1 and clock2). When it is applied to a CMOS switch-capacitor circuit, a “charge sharing” phenomenon will not occur, which is highly advantageous for an accurate linearization process of an analogue signal in an AD converter.

In other embodiments where the non-overlapping clock signal generating module 31 is a voltage controllable non-overlapping clock signal generating module and the ring oscillator 32 is a voltage controllable ring oscillator, the biasing signals p1 and p2 can be correspondingly set as biasing voltage signals, and the magnitude of the voltage of the biasing signals p1 and p2 can be adjustably changed according to a comparison result, thus further correcting the frequency of the third clock signal clock3 and the two phase clock time interval τ. Therefore, in the above embodiments, the two phase clock time interval τ can be corrected in real time (in case where the PVT changes at any time) or be corrected in a one-time manner (in case where the PVT no longer changes) so as to reduce the offset of the two phase clock time interval τ.

In an embodiment, the biasing current signal p1 can be biased to all the gate circuits (e.g., NOT-AND gates and phase inverters) of the ring oscillator 32, i.e., the output end 351 is coupled to all the gate circuits of the ring oscillator 32; the biasing current signal p2 can be also biased to all the gate circuits (e.g., NOT-AND gates and phase inverters) of the non-overlapping clock signal generating module 31, and output end 352 is coupled to all the gate circuits of the non-overlapping clock signal generating module 31. The biasing current signal p2 can be generated in a way of being the mirror of the biasing current signal p1. For example, if the frequency f3 is larger than f4, the comparator module 34 will output a signal so that the current of the biasing current signal p1 output by the programmable biasing signal generating module 35 will be reduced, and the current of p2 will also be reduced. In this way, the frequency f3 of the clock signal clock3 will be reduced, the offset of the two phase clock time interval τ will also be reduced, and the influence by such factors as PVT will be corrected.

It will be understood that the expression “programmable” in the programmable biasing signal generating module 35 indicates a characteristic that the magnitude of the biasing signal output by the programmable biasing signal generating module 35 is adjustable.

The clock generator 30 in the embodiment shown in FIG. 3 can be applied to a switch-capacitor circuit of an AD converter and an analogue filter, for example, and the two phase non-overlapping clock signal provided by the clock generator 30 in not easily influenced by PCT conditions. The offset of the two phase clock time interval is small, and the two phase clock time interval is stable and accurate. Therefore, when a switch-capacitor circuit uses the clock generator 30 of the embodiment, a “charge sharing” phenomenon can be avoided, thus greatly improving the performance of the switch-capacitor circuit.

Although the above example have been described based on a clock generator 30 which generates a two phase non-overlapping clock signal, it is understood that on the basis of the above teaching or enlightenment, those skilled in the art can configure a clock generator which generates a multiple phase non-overlapping clock signal in which the offset of the two phase clock time interval is small. For example, if it is required to generate a multiple phase non-overlapping clock signal having three or more than three phases, the non-overlapping clock signal generating module 31 can be reconfigured equivalently so that it has the function of generating a non-overlapping clock signal having three or more than three phases. The structures and arrangements of other modules (e.g., the frequency detecting module 33, the comparator module 34 and the programmable biasing signal generating module 35) do not have to be changed substantively, except for the adaptive changes made to them.

It will be understood that when a component is referred to as “connected” or “coupled” to another component, it can be connected or coupled directly to the other component, or there can be an intermediate component. Rather, when a component is referred to as “directly connected” or “directly coupled” to another component, there is no intermediate component. Moreover, the expressions “connect” or “couple” used herein can comprise wireless connecting or coupling. As used herein, the term “and/or” comprises any and all combinations of one or more relevant listed items, and can be abbreviated as “/”.

The above embodiments mainly describe the clock generator of the invention and a switch-capacitor circuit using the clock generator. While only some of the embodiments of the invention are described, those skilled in the art will understand that the invention can be carried out in many other ways without departing from the spirit and scope of the invention. Therefore, the illustrated examples and embodiments should be considered as illustrative rather than limiting. The invention may cover various modifications and substitutes without departing from the spirit and scope of the invention defined by the appended claims.

1. A clock generator comprising a non-overlapping clock signal generating module for generating a multiple phase non-overlapping clock signal, characterized by further comprising:
a ring oscillator for generating a third clock signal which reflects the offset of the time interval (τ) between two phase clocks of the multiple phase non-overlapping clock signal;
a frequency detecting module for detecting the frequency of a standard clock signal input by the frequency detecting module and the frequency of the third clock signal;
a comparator module for comparing the frequency of the standard clock signal and the frequency of the third clock signal;
a programmable biasing signal generating module for adjustably outputting a biasing signal according to the comparison result output by the comparator module;
wherein the biasing signal is fed back and input to the ring oscillator so as to adjust the frequency of the third clock signal until the frequency of the third clock signal is compared as be substantially equal to the frequency of the standard clock signal in the comparator module; and
wherein, the biasing signal is fed back and input to the non-overlapping clock signal generating module so as to reduce the offset of the time interval (τ) between two phase clocks.

2. A clock generator according to claim 1, wherein the non-overlapping clock signal generating module is disposed adjacent to the ring oscillator in the chip and is manufactured in synchronization with the ring oscillator in the same process.

3. A clock generator according to claim 2, wherein the phase inverter for generating delay used in the non-overlapping clock signal generating module is the same as the phase inverter for generating delay used in the ring oscillator, and the layouts and structures of them are also the same.

4. A clock generator according to claim 1, wherein the delay (τ1) generated by the phase inverter used in the ring oscillator is n times larger than the time interval (τ) between two phase clocks generated by the phase inverter used in non-overlapping clock signal generating module, wherein n is an integer larger than or equal to 1.

5. A clock generator according to claim 1, wherein the offset of the time interval (τ) between two phase clocks is caused by the fact that the multiple phase non-overlapping clock signal is influenced by the factors of process, voltage and/or temperature.

6. A clock generator according to claim 5, wherein the influence on the third clock signal by the factors of process, voltage and/or temperature is substantially equal to the influence on the multiple phase non-overlapping clock signal by the factors of process, voltage and/or temperature.

7. A clock generator according to claim 1, wherein the non-overlapping clock signal generating module is a current controllable non-overlapping clock signal generating module, the ring oscillator is a current controllable ring oscillator, and the biasing signal is a biasing current signal.

8. A clock generator according to claim 7, wherein the biasing current signal adjusts the magnitude of current according to the comparison result of the comparator module so as to correct the frequency of the third clock signal and the time interval (τ) between two phase clocks.

9. A clock generator according to claim 1, wherein the biasing signal is biased onto all the gate circuits of the ring oscillator, and the biasing signal is also biased onto all the gate circuits of the non-overlapping clock signal generating module.

10. A clock generator according to claim 1, wherein the multiple phase non-overlapping clock signal can be a multiple phase non-overlapping clock signal of two or more than two phases.

11. A clock generator according to claim 1, wherein a reference clock signal generated by crystal oscillator is input to the non-overlapping clock signal generating module.

12. A clock generator according to claim 1, wherein the standard clock signal is not influenced by the factors of process, voltage and/or temperature.

13. A clock generator according to claim 1, wherein the time interval between two phase clocks of the multiple phase non-overlapping clock signal is controlled by the standard clock signal.

14. A switch-capacitor circuit, characterized by comprising a clock generator according to claim 1, wherein the multiple phase non-overlapping clock signal output by the clock generator is applied in the switch-capacitor circuit.
